(19) United States
(12) Patent Application Publication
(10) Pub. No.: US 2001/0052863 A1
(43) Pub. Date: Dec. 20, 2001

(54) System for improved return path performance for digital communication signals using a sampled RF word interface to headend demodulators

(76) Inventors: Robert L. Howald, Chalfont, PA (US); Erik C. Metz, Chalfont, PA (US)

Correspondence Address: Mayer Fortkort & Williams, PC, 200 Executive Dr., Suite 250, West Orange, NJ, 07052, US

(21) Appl. No.: 09/873,160

(22) Filed: Jun. 1, 2001

Related U.S. Application Data
(60) Provisional application No. 60/208,748, filed on Jun. 2, 2000.

(51) Int. Cl. H03M 9/00

(52) U.S. Cl. 341/100

(57) ABSTRACT

An HFC return path system for digital communication signals using a sampled RF word interface to headend demodulators, provides higher performance equipment at an equivalent or lower cost and more flexible and efficient interfacing and traffic multiplexing. The return path signal from the fiber optic node to the headend/hub is represented ones and zeroes, and the digital return receiver at the headend/hub includes an optical receiver for receiving the serial stream of optical ones and zeroes and converting the optical digital signal to an electrical digital signal, a deserializer for deserializing the serial stream of digital words and synchronization information into parallel digital words, a digital filter for processing the deserialized digital words to interface digitally to an application receiver and a digital interface for interfacing and forwarding the processed parallel digital words to the application receiver.

### CROSS-REFERENCE TO RELATED APPLICATIONS

The present invention is related to an invention that is the subject matter of a commonly-assigned co-pending application entitled “HFC Return Path System Using Digital Conversion and Transport”, filed on Apr. 21, 2000 and assigned Ser. No. 09/556,731, which is hereby incorporated by reference. The present invention is also related to U.S. Provisional application 60/208,748 filed Jun. 2, 2000, which is incorporated herein by reference in its entirety.

### FIELD OF THE INVENTION

The present invention relates generally to cable television hybrid-fiber-coax (CATV HFC) return path systems, and more particularly to a system for improving return path performance for digital communication signals using a sampled RF word interface to headend demodulators.

### BACKGROUND OF THE INVENTION

Traditional reverse path CATV Headend and hub equipment for HFC systems have utilized linear optical detection, followed by RF amplification and processing before terminating in a receiver of some design specific to the return path communications being implemented on that particular cable plant. There can be multiple, simultaneous, different return path communications signals using the bandwidth available in the reverse direction, across multiple applications. For traditional HFC in North America, this band is 5-40 MHz. The traditional approach to linking signals transported by the return path fiber is to process the analog signal with the goal of replicating as closely as possible the waveform that originated back at the node. Achieving adequate performance is guaranteed by specifying the laser, receiver, and RF system to assure the signal is not degraded beyond a certain amount necessary for successful communications. However, there are numerous design and implementation issues that make this approach difficult and costly, including analog laser specifications, laser second order response characteristics, optical link length constraints, costly test and specification-intensive analog headend equipment, calibration and maintenance of analog parameters, quality of equipment sensitive to traffic and added impairment by existing equipment. All of these factors contribute to the overall cost issue of developing high performance analog equipment.

These problems have previously been addressed with continued development in improved analog lasers and return path receiver performance, higher power lasers and modification of HFC architectures. However, each of the above-noted issues and problems are still presented.

The present invention is therefore directed to the problem of developing a return path system for digital communication signals, using a sampled RF word interface to headend demodulators, that provides lower cost equipment design, higher performance equipment at an equivalent or lower cost and more flexible and efficient interfacing and traffic multiplexing.

### SUMMARY OF THE INVENTION

The present invention improves the return path performance for digital communication signals by using a sampled RF word interface to headend demodulators, i.e., the information content contained in the samples delivered by a digital return path are delivered directly to an appropriately implemented application receiver prepared to interface directly, thereby eliminating the typical D/A conversion step and eliminating possible impairment caused thereby.

According to one embodiment of the present invention, a method to recover a return path signal represented entirely as ones and zeros in a cable television system includes the steps of (1) receiving a serial stream of digital words with appropriate synchronization information to identify the boundaries between words and to recover timing of the bits themselves; (2) deserializing the serial stream of digital words and synchronization information; (3) processing the deserialized digital words as necessary to interface digitally to an application receiver; and (4) forwarding the processed parallel digital words to the application receiver.

Another embodiment of the invention is directed to a system for a recovering a return path signal of digital words, in a hybrid fiber-coax cable television system using baseband serial optical transport, in which the return path signal from the fiber optic node to the headend/hub is represented by encoding it entirely as ones and zeroes. The system includes a digital return receiver and any number of application receivers. The digital return receiver of the system includes an optical receiver for receiving a serial stream of optical ones and zeroes from an optical fiber and converting the optical digital signal to an electrical digital signal, a deserializer for deserializing the serial stream of digital words and synchronization information, a digital filter for processing the deserialized digital words to interface digitally to an application receiver and an interface for interfacing and forwarding the processed parallel digital words to at least one of the application receivers.

In each of the embodiments the digital filter or processing step eliminates front end analog stages of the digital words, provides a digital word interface directly to a data bus to a digital receiver portion of a demodulator of the application receiver and replaces the functionality of the front end analog stages with equivalent digital functionality.

The system and/or method may be implemented at a CATV headend or hub.

In a preferred embodiment of the invention, if the digital receiver's data bus is smaller than the parallel word length, the digital filter or digital processing step truncates the least significant bits to interface to the at least one application receiver. In addition, if the word size of the digital receiver exceeds that of the transmission link, the parallel word is padded with zeros.

Finally, a logical translation device may be used to interface between the application receiver and the transport link or may be part of the application receiver. A Field Programmable Gate Array (FPGA) may be used as the device.

### BRIEF DESCRIPTION OF THE DRAWINGS

The above-mentioned and other objects, features and advantages of the present invention will become more apparent from the following detailed description when taken in conjunction with the accompanying drawing, wherein:

FIG. 1 depicts the basic elements of a digital return path transport system with direct digital hand-off to headend receivers according to present invention.

### DETAILED DESCRIPTION

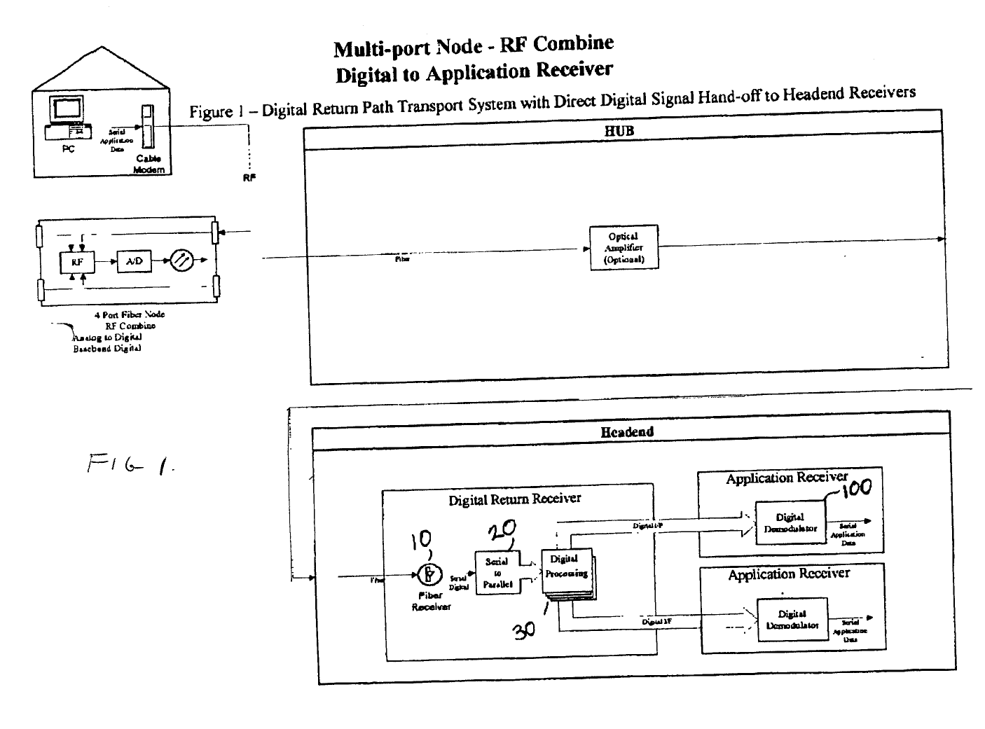

The basic elements of the proposed system and method for improved return path performance for digital communication signals, using a sampled RF word interface to headend demodulators, are shown in the simplified block diagram of FIG. 1.

Essentially, the reverse path of a CATV headend or hub can sustain communications from multiple, varying transmit sources from subscriber homes. This invention relies first on the availability of an advanced reverse path implementation. Such a system transports information using an entirely different method than described above, beginning at the node. The advanced approach, filed under separate disclosure as noted above under Cross-Reference to Related Applications, is to sample the analog waveform that arrives at the node from the users on the return path. Subsequently, the samples can be digitally encoded so that the link from transmitter to Headend/Hub can be made with digital optical transmitters and receivers. Thus, the transported information in this system becomes a string of bits.

There are multiple advantages to the digital return approach, outlined in the previously-noted disclosure. Most significant for this disclosure is the virtual elimination of impairment after analog-to-digital conversion (A/D conversion) at the node. The requirement of the optics now is merely to behave as a reliable binary system, reproducing one of two analog values. In digital terms, these values are zero “0” and one “1”, and are represented by two different optical levels. This approach to the optical link for HFC removes or mitigates to a great extent many of the impairment issues associated with laser transmitters, fiber nonlinearities, optical receivers, and RF amplifiers.

As noted in the corresponding application, the optical transmitter at the node receives a serial stream of digital words and transmits the digital words to an optical receiver. The implementation of an all bit stream at the RF-to-optical conversion point immediately brings into the equation the idea of standardized transport and simplifies network implementation, accelerates development, and brings with it a comfort level of a proven, robust technology into the HFC infrastructure. In addition, because of the distance advantage, passive equipment or complete removal of hub repeater sites can be a possibility.

However, the elimination of impairment beyond the node rests on the ability to recover the transported digital words at the Headend without impairment. The following, with reference to FIG. 1, describes a system and method to perform this operation, i.e., to provide digital word interfaces between HFC return path communications links and termination equipment receivers.

In the disclosure mentioned previously, several advantages are described. However, the processing performed by the digital optical system in that case ends by replicating the broadband analog output signal using a digital-to-analog converter (D/A). This approach is valuable from the standpoint of legacy systems, some of which may still implement analog receiver technology. However, for sophisticated reverse path transmissions, such as cable modems, there is a better way to interface to the demodulation equipment.

The proposed approach to interfacing with Headend termination equipment takes advantage of developments in application specific integrated circuits (ASICs), very large-scale integrated circuits (VLSI) and digital signal processing (DSP). Modern modem technology incorporates digital receiver technology—receivers on a chip—implementing many complex synchronization, equalization, and detection functions on a single digital IC or within a chipset. These functions are able to be performed digitally because the typical modern communications receiver will tune to the channel of interest, filter it, and then sample the filtered waveform at periodic increments.

As in the description above for the activity at the node, the information represented by the samples can be subsequently converted to bits for digital processing in the remainder of the receiver. This is done by numerically representing each analog sample with an N-bit word, where N is the number of bits of resolution in the A/D converter (e.g. 8, 10, 12). Great strides have been made in designing VLSI circuits for communications applications, and high-speed data receivers are taking advantage of these advances. HFC systems now also can take advantage of these processes by eliminating the D/A conversion step for application demodulators that have digital receivers. Removal of this step, and instead interfacing directly to the digital receivers using the available digital words, provides a mechanism by which impairment can be eliminated, and analog equipment shelves in Headends (or Hubs) can be simplified to digital networking busses and cards.

Refer to FIG. 1 which shows a complete digital return path system for clarity. It will be appreciated by those skilled in the art that while the technology under discussion with respect to FIG. 1 is located in the “Headend” section of the figure, it could also reside at a hub site, depending on the overall HFC architecture in use. The function of the D/A converter in a digital return system is to reconstruct the broadband 5-40 MHz input that existed at the node. Subsequently, this RF signal would be processed as the reverse path signal is processed today at the output of the traditional return path receiver (RPR) equipment. That is, it would be split, amplified, attenuated, etc., prior to being connected to the application receiver, which recovers the information. However, this analog process, including the D/A itself, contributes to signal degradation and potential loss or impairment of the information being carried, as well as intricate level setting issues. For a sophisticated receiver, such as a cable modem, the RF signal would be downconverted to an intermediate frequency or baseband in the receiver front end. Then, it would be sampled using an A/D converter that resides within the receiver and re-converted to a digital signal for information recovery. This complete Headend process—D/A conversion, amplification, splitting, tuning, A/D conversion—is unnecessarily complicated by the intermediate conversion to analog, which additionally imparts undesirable signal impairment.

However, the need to always interface to receivers using the traditional return path RF input because of their wide bandwidth has been eliminated by recent advances in high-speed digital processing. Thus, the information content contained in the samples delivered by a digital return path system can be delivered directly to an appropriately implemented application receiver prepared to interface digitally. In FIG. 1, this is shown in the “Headend” block by augmenting the digital return receiver with an additional functional element labeled “Digital Processing”. More specifically, in FIG. 1, a serial stream of digital words transported over the optical link is received at fiber receiver 10. A serial-to-parallel converter (SERDES) or “deserializer” 20 converts the serial stream of digital words to parallel digital words and delivers the parallel word to digital processing block 30. “Digital Processing” actually refers to each of the processing stages required to complete the functionality that must exist between the data words representing the analog samples and the application receivers, including actual filter functions. This approach requires the digital return receiver to:

eliminate front end analog stages;

provide a digital word interface directly to the data bus (or buffer) to the digital receiver portion of digital demodulator 100; and

replace the functionality of the front end analog stages with equivalent digital functionality, if necessary.

Note that, with reference to (3), an important piece of the front end functionality was to adjust the analog level to properly drive the receiver's A/D converter. It will be appreciated that this key piece of functionality is no longer necessary. Additionally, digital receivers already implement the final, fine tuning stages for synchronization within the digital section. Thus, the final conversion to baseband is already a digital function, and the technology of digital tuners is well developed. The core functionality of a digital front end is thus digital filtering and extension of the synchronization function.

Those skilled in the art will appreciate that an important consideration for proper implementation of the digital hand-off is the “interface definition” between the digital transport mechanism and the application receiver. This interface consists of an N-bit parallel word that represents payload information, and the appropriate hand-shaking required to communicate between the two subsystems (digital return and digital receiver). In addition, the interface includes the necessary synchronization of the clock signals on each side. Again, the digital transport approach for the return path implements serial baseband transmission from node to Headend or Hub. The serial stream is bit and word synchronized, and the parallel word that numerically represents the original samples taken at the node is presented at the output.

Depending on the specific implementation of the digital return, the parallel word size can vary. A digital receiver's data bus, which carries the sampled information for the device, is generally of fixed size. This bus size is expected to be smaller than the parallel word length available. In such a case, the least significant bits (LSB's) from the transport system will be truncated to interface to the application receiver. There is information lost in this process, but it is information that would have been lost in any case since it is a limit that is set within the digital receiver IC.

In addition, if the word size of the digital receiver itself exceeds that of the transmission link, then the parallel word will be handed off by padding it with zeroes in the extra bits. In this topology, effects of the lower resolution must be evaluated. This, however, would be an atypical case, as it is common in the art to assure that the transmission link exceeds modem performance parameters to minimally impair the transmission.

Another important piece of the interface is the “language”, or protocol, spoken to assure communication is successful and efficient. Application receivers traditionally have proprietary implementations, and particularly so for the digital portions within the design of a receiver with both analog and digital functions. Such receivers can be interfaced to by implementation of logical translation device such as with a Field Programmable Gate Array (FPGA) that processes the data words from the transport link through it, and formats them properly for the receiver's data bus. The digital processing may be implemented with an FPGA (those skilled in the art will appreciate that while the FPGA may be a part of the digital return receiver, a separate FPGA may also be part of an application receiver as noted below, but, in general, this is not the case). Some proprietary receivers may not have the data bus accessible, or be completely analog receivers, in which case the digital return with D/A reconstruction will be necessary. However, modern receivers have more well-defined, architectural interfaces, either through common use of existing art or through committee-developed implementations to assure standardization. In this case, implementation involves designing access to the receiver data bus during circuit development of the advanced receivers, and implementing a gate array or translation device on the receiver itself to communicate the digital return word sequence to the receiver.

In modern receiver development, direct digital interface definition can be applied immediately to new designs because the existing art includes processing within the high-speed data receiver consistent with the type of interface necessary between transport link and receiver data bus. In legacy systems, constraints on accessibility to receiver functions may require alternative interface equipment be developed that permit access to the digital functionality. Finally, some legacy systems, and particularly all analog receivers, will not be able to avail themselves to the advantages without complete redesign. In such a case the D/A output approach may be best suited. In most such cases, however, such a receiver design will be operating on extremely simple modulation functions, and a digitized implementation can quickly be developed and deployed. It is also the case that these simpler receivers will see the least performance benefit from the digital interface, as the added analog impairment of reconstruction is insignificant to the link performance for these typically simple modulation schemes.

The list of potential short term benefits of the proposed system and method using a sampled RF word interface to headend demodulators for digital communication signals are apparent: significant flexibility in applying processing enhancements, the ability to flexibly interface CATV headend termination equipment, etc. However, perhaps the most benefit is in the years to come, as the conversion of the return path to all bits opens up many networking possibilities associated with processing, transport, multiplexing, and terminating equipment interfaces.

Although various embodiments are specifically illustrated and described herein, it will be appreciated that modifications and variations of the present invention are covered by the above teachings and within the purview of the appended claims without departing from the spirit and scope of the invention.

What is claimed is:

1. A method to recover a return path signal represented entirely as ones and zeros in a cable television system comprising the steps of:
receiving a serial stream of digital words with appropriate synchronization information to identify the boundaries between words and to recover timing of the bits themselves;
deserializing the serial stream of digital words and synchronization information;
processing the deserialized digital words to interface digitally to an application receiver; and
forwarding the processed parallel digital words to the application receiver.

2. A method according to claim 1, wherein said processing step comprises the steps of:
eliminating front end analog stages of the digital words;
providing a digital word interface directly to a data bus to a digital receiver portion of a demodulator of the application receiver; and
replacing the functionality of the front end analog stages with equivalent digital functionality.

3. A method according to claim 1, wherein said method is performed at a CATV headend.

4. A method according to claim 1, wherein said method is performed at a CATV hub.

5. A method according to claim 1, wherein the application receiver includes a digital demodulator with a digital receiver.

6. A method according to claim 5, wherein if the digital receiver's data bus is smaller than the parallel word length, a digital filter truncates the least significant bits to interface to the application receiver.

7. A method according to claim 5, wherein if a word size of the digital receiver exceeds that of the transmission link, the parallel word is padded with zeros.

8. A method according to claim 1, wherein a logical translation device interfaces between an application receiver and the transport link.

9. A method according to claim 8, wherein the logical translation device is part of the application receiver.

10. A method according to claim 9, wherein the logical translation device is a Field Programmable Gate Array (FPGA).

11. A method according to Claim 10, wherein said FPGA processes the data words after the deserializing step deserializes the serial stream of digital words and synchronization information and formats the data for the application receiver's data bus.

12. A system for a recovering a return path signal of digital words, in a hybrid fiber-coax cable television system using baseband serial optical transport, in which the return path signal from the fiber optic node to the headend/hub is represented by encoding it entirely as ones and zeroes, the system including a digital return receiver and a plurality of application receivers, the digital return receiver of the system comprising:
conversion/receiving means for receiving a serial stream of optical ones and zeroes from an optical fiber and converting the optical digital signal to an electrical digital signal;
means for deserializing the serial stream of digital words and synchronization information;
digital processing means for processing the deserialized digital words to interface digitally to an application receiver; and
interface means for interfacing and forwarding the processed parallel digital words to at least one of the plurality of application receivers.

13. A system according to claim 12, wherein said digital processing means comprises:
means for eliminating front end analog stages of the digital words;
means for providing a digital word interface directly to a data bus to a digital receiver portion of a demodulator of the application receiver; and
means for replacing the functionality of the front end analog stages with equivalent digital functionality.

14. A system according to claim 12, wherein said system is implemented at a CATV headend.

15. A method according to claim 12, wherein said system is implemented at a CATV hub.

16. A system according to claim 12, wherein the at least one application receiver includes a digital demodulator with a digital receiver.

17. A system according to claim 16, wherein if the digital receiver's data bus is smaller than the parallel word length, a digital filter of said digital processing means truncates the least significant bits to interface to the at least one application receiver.

18. A system according to claim 16, wherein if a word size of the digital receiver exceeds that of the transmission link, the parallel word is padded with zeros.

19. A system according to claim 12, wherein a logical translation device interfaces between the at least one application receiver and the transport link.

20. A system according to claim 19, wherein the logical translation device is part of the application receiver.

21. A system according to claim 20, wherein the logical translation device is a Field Programmable Gate Array (FPGA).

22. A system according to claim 21, wherein said FPGA processes the data words after said deserializing means deserializes the serial stream of digital words and synchronization information and formats the data for the application receiver's data bus.
